(19) United States
(12) Patent Application Publication
(10) Pub. No.: US 2010/0244032 A1
(43) Pub. Date: Sep. 30, 2010

(54) ALUMINUM-NICKEL ALLOY WIRING MATERIAL, DEVICE FOR A THIN FILM TRANSISTOR AND A THIN FILM TRANSISTOR SUBSTRATE USING THE SAME, AND METHOD OF MANUFACTURING THE THIN FILM TRANSISTOR SUBSTRATE

(75) Inventors: Pil Sang YUN, Seoul (KR); Byeong-Beom KIM, Suwon-si (KR); Changoh JEONG, Suwon-si (KR); Yangho BAE, Seoul (KR); Shigeki TOKUCHI, Ageo-shi (JP); Ryoma TSUKUDA, Ageo-shi (JP); Yoshinori MATSUURA, Ageo-shi (JP); Takashi KUBOTA, Ageo-shi (JP)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/751,136

(22) Filed: Mar. 31, 2010

(30) Foreign Application Priority Data
Mar. 31, 2009 (JP) 2009-085484
Nov. 10, 2009 (KR) 10-2009-0108235

(51) Int. Cl. H01L 29/786; H01L 21/283; C22C 21/00; C23C 14/34

(52) U.S. Cl. 257/57; 438/674; 420/550; 204/298.13; 257/E29.291; 257/E21.159

(57) ABSTRACT

An Aluminum-Nickel alloy wiring material includes Aluminum, Nickel, Cerium, and Boron. A thin film transistor includes the Aluminum-Nickel alloy wiring material. A sputtering target comprises Aluminum, Nickel, Cerium and Boron. A method of manufacturing a thin film transistor substrate comprises disposing a thin film transistor on a substrate, wherein the thin film transistor includes a wiring circuit layer comprising Aluminum, Nickel, Cerium, and Boron. The Nickel, Cerium and Boron satisfy the following inequalities; 0.5≦X≦5.0, 0.01≦Y≦1.0, and 0.01≦Z≦1.0, respectively, wherein X represents an atomic percentage of Nickel content, Y represents an atomic percentage of Cerium content, and Z represents an atomic percentage of Boron content.

This application relies for priority upon Japanese Patent Application No. 2009-85484 filed on Mar. 31, 2009 and Korean Patent Application No. 2009-0108235 filed on Nov. 10, 2009, and all the benefits accruing therefrom under 35 U.S.C. §119, the contents of which in their entirety are herein incorporated by reference.

### BACKGROUND OF THE INVENTION

1. Field of the Invention

The present invention relates to an Al—Ni alloy wiring material used in a display apparatus such as a liquid crystal display (“LCD”). More particularly, the present invention relates to an Al—Ni—B—Ce alloy wiring material suitable for a display apparatus including a thin film transistor (“TFT”) or a transparent electrode, and a device structure using the same.

2. Description of the Related Art

Recently, display apparatuses have been extensively used in a variety of information appliances such as audio-visual (“AV”) appliances, household appliances which employ thin film transistors (“TFTs”), and other similar devices. The display apparatuses may include flat panel display devices such as liquid crystal displays (“LCDs”) and organic light emitting diode (“OLED”) displays. Various control structures for the display apparatuses have been suggested, such as an active matrix and passive matrix control structures. The control structures have circuits typically including thin films.

In general, and specifically in the active matrix control structure, the display apparatuses include a transparent electrode, a thin film transistor, and a conductive electrode for wiring. Materials used in the display apparatuses exert an influence upon display quality, power consumption, and product price of the resulting display apparatus.

Various technologies for the display apparatuses have been developed, which will be described below in detail with reference to a typical LCD.

The typical LCD has occupied an important market position within the field of display apparatuses because it may display in high definition at a low price. The typical LCD has mainly employed a TFT structure, and a wiring material of the TFT typically includes an aluminum (Al) alloy. Since the Al has low electrical resistivity and facilitates a wiring process, the Al is used as a substitute for high melting-point materials used in the related art such as tantalum (Ta), chromium (Cr), titanium (Ti) and alloys thereof, which have high electrical resistivity.

The wiring material of a TFT may also have an Aluminum-Nickel (“Al—Ni”) composition. However, the Al—Ni alloy wiring material suggested in the related art has the following problems. First, when a device circuit is formed using the Al—Ni alloy wiring material, the Al—Ni alloy may be corroded if the Al—Ni alloy wiring material comes in contact with a developer used to form the circuit. In addition, it is difficult for the Al—Ni alloy wiring material to be adapted for a conventional manufacturing process in many cases. Since the contact portion of the Al—Ni alloy wiring material with the developer is melted in an etch process, even if the Al—Ni alloy wiring material is corroded by the developer, problems do not occur in the formation of a circuit. However, when the manufacturing process is re-started from the development process after stripping a resist due to failure occurring in a development process, that is, when a photolithography reworking process is performed, problems do occur. Since the Al—Ni alloy is melted due to the corrosion by the developer in the development process that has been performed when the photolithography rework process is performed, the photolithography rework process is made very difficult or even impossible. Therefore, an Al—Ni alloy wiring material having corrosion resistance against the developer has been required in order to increase the product yield by employing the photolithography rework process.

For these reasons, an Al—Ni alloy wiring material, which is capable of overcoming various problems of melting the Al—Ni alloy due to the corrosion of the developer leading to difficulty forming the formation of a circuit, oxidizing the surface of the Al—Ni alloy layer, or increasing a contact resistance value where there is direct contact with the transparent electrode, has been required. Accordingly, in order to improve resistance of the Al alloy wiring material against the corrosion by the developer, a technology of nitrifying or oxidizing the surface of the Al alloy layer has been suggested.

However, if the surface of the Al alloy layer is nitrified or oxidized, a sputtering time is extended when a thin film is formed. In addition, since nitrogen gas (N₂) or oxygen gas (O₂) must be introduced into a chamber of a sputtering system in order to nitrify or oxidize the Al alloy layer, particles may be easily generated in the sputtering process, and a superior Al alloy layer may not be formed. When forming a circuit by etching the Al alloy layer having a nitride layer or an oxide layer, since different etch rates are employed between the nitride layer or the oxide layer formed on the surface of the Al alloy layer and a remaining portion of the Al alloy layer other than the nitride layer or the oxide layer, an etch process is slowly performed with respect to the nitride layer or the oxide layer on the surface of the Al alloy layer. Therefore, since residues exist on the surface of the Al alloy layer after the etch process has been performed, the circuit may have an undesirable reverse-tapered profile. In order to normalize the profile of the circuit, a special etchant may be used. However, the manufacturing cost may be correspondingly increased. As described above, an Al alloy wiring material having superior corrosion resistance against a developer used in the formation of the circuit has been required.

Second, the Al—Ni alloy wiring material that directly contacts the transparent electrode is corroded when a contact hole is formed in the TFT device because the Al—Ni alloy wiring material is exposed through the contact hole.

The contact hole of the TFT device is formed by depositing an insulating layer including silicon nitride (SiNx) on a circuit layer including the Al—Ni alloy wiring material and formed on a substrate through a plasma chemical vapor deposition (“CVD”) scheme or a sputtering scheme. Then, after depositing a resist layer on the surface of the insulating layer, patterning is performed through an exposure and development process to form the contact hole in the insulating layer. Thereafter, the contact hole is formed in the insulating layer through a dry etch process using carbon tetrafluoride (CF₄) gas or sulfur hexafluoride (SF₆) gas. Subsequently, the resist layer is stripped, and cleaning and drying processes are performed. Thereafter, a transparent electrode layer is formed on the insulating layer having the contact hole using a transparent electrode material such as Indium Tin oxide (“ITO”).

When the contact hole is formed, gas of the dry etch process or a stripping solution for the resist comes into contact with the surface of the circuit including the Al—Ni alloy wiring material. In this case, corrosion and a deterioration, such as a black spot, is created on the circuit surface including the Al—Ni alloy wiring material exposed through the contact hole.

In order to prevent the corrosion in the formation of the contact hole, a dry etch method using CF₄ gas or an improved method of stripping a resist has been suggested.

However, since the CF₄ gas etches SiN_{X} at a lower etch rate than that of SF gas, the etch time is extended and the manufacturing process is ineffectively performed. In addition, when the stripping process is performed for the resist using a non-aqueous stripping solution, the stripping process must be performed at a high temperature of about 60° C. to about 80° C. Accordingly, the manufacturing cost is increased. In addition, since the entire equipment must be prevented from exploding in order to use the non-aqueous stripping solution such as isopropyl alcohol in a cleaning process after the resist has been stripped, the cost of facilities is increased. Accordingly, an Al alloy wiring material having superior corrosion resistance in the formation of the contact hole as well as corrosion resistance against the developer has been required.

Recently, as the screen of the display apparatus increases in size, the area of a substrate for the display apparatus must be significantly increased. Accordingly, the following unexpected problems have been indicated. In order to manufacture the substrate having a large area, for example, a substrate having an area over 600 cm², particularly, an area of 4000 cm², a great number of devices, e.g., individual TFTs, are formed on one substrate. For example, the 600 cm² substrate includes 10⁶ or more devices. Devices of the substrate having a large area, which are in the direct contact between the transparent electrode layer and the circuit layer including the Al alloy wiring material, have irregular contact resistance values across the display, leading to display defects.

In a display apparatus having devices in direct contact with the transparent electrode layer and manufactured by using the Al—Ni alloy wiring material that has been suggested in the related art, contact resistance values of the devices are measured at 9 points including four edges of a square substrate having an area of 1740 cm², the centers of four lateral sides of the square substrate, and the center of the square substrate. The contact resistance values of the devices vary in the range of 60 Ω/□10 μm to 1500 Ω/□10 μm.

Since the irregular contact resistance values of the devices formed in the substrate greatly affect the manufacturing cost and the reliability of a product, the irregular contact resistance values cause a serious problem. In addition, the uniformity of contact resistance values of the devices on the surface of one substrate are an important subject in the display apparatus, the area of which has gradually increased in size over the last several years. Accordingly, an Al alloy wiring material capable of solving the above problems is required.

### BRIEF SUMMARY OF THE INVENTION

An exemplary embodiment of the present invention provides an Al—Ni alloy wiring material which can directly make contact with a transparent electrode layer, has superior corrosion resistance against a developer and superior corrosion resistance in the formation of a contact hole, and allows devices to have constant contact resistance values even though the devices are formed on a substrate having a large area, and a device structure, such as device for a thin film transistor or a thin film transistor substrate, using the same.

In one exemplary embodiment, an aluminum-nickel (“Al—Ni”) alloy wiring material includes Al, Ni, Cerium (Ce) and Boron (B), wherein the Ni, Ce, and B contents satisfy the following inequalities; 0.5≦X≦5.0, 0.01≦Y≦1.0, and 0.01≦Z≦1.0, wherein X represents an atomic percentage of Nickel content, Y represents an atomic percentage of Cerium content, and Z represents an atomic percentage of Boron content.

In another exemplary embodiment, a device for a thin film transistor includes; a wiring circuit layer formed using the Al—Ni alloy wiring material having the above described composition, a semiconductor layer disposed on the wiring circuit layer and a transparent electrode layer disposed on the semiconductor layer, wherein at least a portion of the wiring circuit layer contacts the transparent electrode layer.

In still another exemplary embodiment, a device for a thin film transistor includes a wiring circuit layer formed using the Al—Ni alloy wiring material having the above described composition, a semiconductor layer disposed on the wiring circuit layer, and a transparent electrode layer disposed on the semiconductor layer, wherein a portion of the wiring circuit layer directly contacts the semiconductor layer.

In still another exemplary embodiment, a sputtering target includes AL, Ni, Ce and B, wherein the Ni, Ce and B contents satisfy the following inequalities; 0.5≦X≦5.0, 0.01≦Y≦1.0, and 0.01≦Z≦1.0, wherein X represents an atomic percentage of Nickel content, Y represents an atomic percentage of Cerium content, and Z represents an atomic percentage of Boron content.

In still another exemplary embodiment, a thin film transistor substrate includes; a substrate, a first wiring circuit layer disposed on the substrate and comprising a gate electrode, a gate insulating layer disposed on the substrate, a semiconductor layer disposed on the gate insulating layer, a second wiring circuit layer disposed on the semiconductor layer and including a source electrode and a drain electrode, an insulating layer disposed on the source electrode and the drain electrode and comprising a contact hole formed at a side of the source electrode, and a transparent electrode disposed on the insulating layer and connected with the source electrode through the contact hole.

In still another exemplary embodiment, a method of manufacturing a thin film transistor substrate includes; forming a thin film transistor including a wiring circuit layer and a semiconductor layer on a substrate, coating a photoresist on the substrate including the wiring circuit layer, removing a portion of the photoresist and forming a contact hole using the photoresist as a mask to expose a portion of the wiring circuit layer through the insulating layer, wherein the substrate including the wiring circuit layer that has been exposed is ashed, and the photoresist is stripped, and wherein the substrate on which the photoresist has been stripped is cleaned by using an organic cleaning solution, and a transparent electrode is disposed on the insulating layer and connected with the wiring circuit layer through the contact hole.

As described above, according to the present invention, the Al—Ni alloy wiring material having superior corrosion resistance against the developer and in the formation of the contact hole can be provided. Accordingly, a device having a direct contact structure with the transparent electrode layer can be stably manufactured. In addition, devices formed on the surface of the substrate having a large area have constant contact resistance values.

### BRIEF DESCRIPTION OF THE DRAWINGS

The above and other advantages of the present invention will become readily apparent by reference to the following detailed description when considered in contact with the accompanying drawings wherein:

FIG. 1 is a cross-sectional view showing an exemplary embodiment of a thin film transistor (“TFT”) according to the present invention;

FIG. 2 is a graph comparing a measured contact resistance value when an ashing process and when an ashing process is not adopted;

FIG. 3 is a graph showing a contact resistance value between a source electrode and an indium tin oxide (“ITO”) layer when performing an additional cleaning process using an organic cleaning solution before an ITO electrode is formed;

FIG. 4 is a photograph showing an evaluation for black spots;

FIG. 5 is a front-perspective view schematically showing a test sample in which an ITO electrode layer is stacked on an Al alloy electrode layer while being disposed oblique to the Al alloy electrode layer; and

FIG. 6 is a top plan view showing samples used to evaluate the irregularity of a contact resistance surface.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

Hereinafter, an exemplary embodiment of the present invention will be described. An exemplary embodiment of an Aluminum-Nickel (“Al—Ni”) alloy wiring material according to the present invention is suitable for a display apparatus, such as those used in an information appliance, an audio visual (“AV”) appliance, a household appliance, etc., so that the display apparatus can present high definition image quality and display an image at a high speed. Hereinafter, an active matrix liquid crystal display (“LCD”) adaptable for the present invention will be described as an example. The present invention is not limited to the active matrix LCD, but is adaptable as a wiring material for use in various display apparatuses.

The active matrix LCD has a device structure including a thin film transistor (“TFT”) serving as a switching device, a transparent electrode including indium tin oxide (“ITO”), indium zinc oxide (“IZO”), or other material with similar characteristics (hereinafter, referred to as “transparent electrode layer”), and a wiring circuit including an Al alloy wiring material. The above device structure includes at least one of a contact part between the wiring circuit and the transparent electrode layer, and a contact part between the wiring circuit and an n+-Si layer (for example, a semiconductor layer doped with phosphorus (P)) in the TFT.

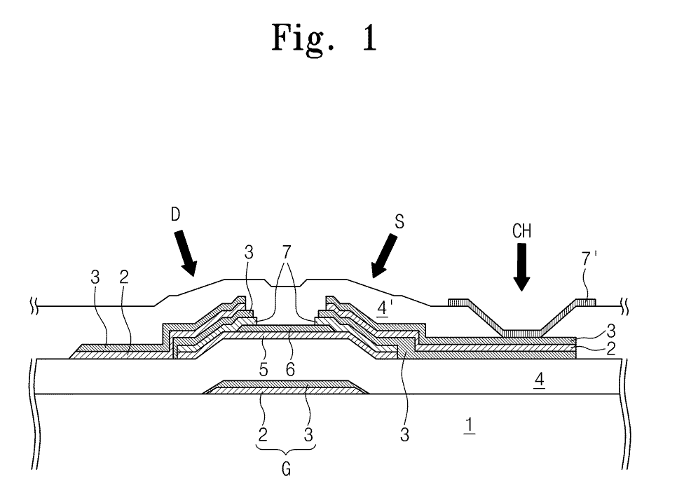

Hereinafter, the device structure of the active matrix LCD will be described in detail with reference to FIG. 1. FIG. 1 is a sectional view schematically showing a TFT including amorphous silicon (a-Si) in the active matrix LCD. In the TFT structure, a substrate 1 is provided thereon with a wiring circuit layer 2, which includes the Al alloy wiring material, which includes a gate electrode G, and a cap layer 3 (a contact barrier layer is referred to as the cap layer 3 in FIG. 1), which includes an alloy of Molybdenum (Mo) or Mo-Wolfram. A gate insulating layer 4, which may include silicon nitride (SiNx), is disposed on the gate electrode G to protect the gate electrode G. An amorphous-Silicon (“a-Si”) semiconductor layer 5, a channel protective layer 6, an n-doped Silicon (n+-Si) semiconductor layer 7, a cap layer 3, and the wiring circuit layer 2 are sequentially stacked on the gate insulating layer 4. Then, the stacked layers are patterned, thereby forming a drain electrode D and a source electrode S. An insulating layer 4′ is formed on the drain electrode D and the source electrode S, wherein the insulating layer 4′ includes SiNx, resin or other similar material for planarization of the device surface. A contact hole CH is formed in the insulating layer 4′ corresponding to a portion of the source electrode S, and a transparent electrode layer 7′, embodiments of which include ITO, IZO or other similar materials, is formed on the insulating layer 4′ and on an area where the contact hole CH is formed. When the wiring circuit layer 2 includes the Al alloy wiring material, the cap layer 3 is interposed between the n+-Si semiconductor layer 7 and the wiring circuit layer 2 and/or between the transparent electrode layer 7′ of the contact hole CH and the wiring circuit layer 2.

If the embodiment of an Al—Ni alloy wiring material according to the present invention is employed, the cap layer 3 shown in FIG. 1 can be omitted, and a device can be formed in a state in which the transparent electrode 7 directly contacts the wiring circuit layer 2 without degradation of the materials of the transparent electrode 7 or the wiring circuit layer 2. When a device of FIG. 1 is manufactured using the Al alloy wiring material according to the related art, an effect of Al oxide formed in the Al alloy wiring material must be taken into consideration when designing the device. Accordingly, the cap layer 3 is formed between a wiring circuit including the Al alloy and the transparent electrode. The cap layer 3 includes a high-melting point metallic material such as Mo or Titanium (Ti). When the Al—Ni alloy wiring material according to an exemplary embodiment of the present invention is used, the cap layer can be omitted from the device. However, the present invention is not limited thereto, and is adaptable to a device having a cap layer similarly to the related art.

According to an exemplary embodiment of the present invention, the Al—Ni alloy wiring material includes Ni, Cerium (Ce) and Boron (B). The Ni, Ce and B content in the Al—Ni alloy meets the following inequalities 0.5≦X≦5.0, 0.01≦Y≦1.0, and 0.01≦Z≦1.0, respectively, wherein X represents an atomic percentage (“at %”) of Nickel content, Y represents an at % of Cerium content, and Z represents an at % of Boron content in the Al—Ni alloy.

The Ni forms an inter-metallic compound with Al, e.g., through heat treatment, and provides a superior contact characteristic in the case of direct contact with the transparent electrode layer. If the Ni content exceeds the above range, the resistivity of the wiring circuit is disadvantagedly increased. If the Ni content is less than the above range, an amount of the inter-metallic compound created between Ni and Al is reduced, Ni cannot make a direct contact with the transparent electrode layer, and heat resistance (wherein heat resistance refers to a suppressing action against plastic deformation of the Al—Ni alloy wiring material caused by heat) is degraded. Accordingly, exemplary embodiments include configurations wherein Ni content is in a range of about 0.5 at % to about 5.0 at %.

In detail, if the Ni content exceeds about 5 at %, the resistivity of the wiring material is excessively increased, a defect called a dimple may form on the surface of the wiring material, and the heat resistance of the wiring material cannot be ensured. In addition, a phenomenon known as black spot corrosion may occur when the contact hole is formed.

Meanwhile, if Ni content is less than about 0.5 at %, a protrusion called a hillock may form on the surface of the wiring material, and heat resistance of the wiring material cannot be ensured. If the device is continuously operated, a contact part directly making contact with the ITO layer may be damaged over a long period of use. As used herein, the term dimple refers to a fine defect occurring on a material surface due to stress generated when the Al—Ni alloy wiring material is subject to heat treatment. The dimple exerts a negative influence on the contact characteristic of the wiring material and reduces contact reliability. Meanwhile, as used herein, the term hillock refers to a protrusion formed on the material surface due to a stress generated when the Al—Ni alloy wiring material is subject to heat treatment. The hillock also exerts a negative influence on the contact characteristic of the wiring material and reduces contact reliability. Both of the dimple and the hillock are formed due to deformation of the Al—Ni alloy wiring material by heat, called stress migration. The heat resistance of the Al—Ni alloy wiring material is determined according to the dimple and/or the hillock density on a surface of the wiring material.

If Ce is contained in the exemplary embodiment of an Al—Ni alloy according to the present invention, the Ce can improve corrosion resistance against the developer used for forming the contact hole and prevent black spots from being formed on the surface of the Al—Ni alloy wiring material when the contact hole CH is formed. In order to provide the corrosion resistance, exemplary embodiments include configurations wherein the Ce content is in the range of about 0.01 at % to about 1.0 at %. If the Ce content is less than about 0.01 at %, black spot corrosion may still occur when the contact hole CH is formed. If the Ce content exceeds about 1.0 at %, the resistivity of a wiring material and the contact resistance value when the wiring material is in direct contact with the transparent electrode layer are increased. In addition, if the Ce content exceeds about 1.0 at %, a crystalline structure of Al₁₁Ce₃ of a sputtering target, which is used to form a layer, has a macro-size, and segregation of the Ce is created so that the sputtering process may undesirably not be uniformly performed.

When the Al—Ni alloy containing not only Ce but also B directly contacts a semiconductor layer including n+-Si, the mutual diffusion of the Al and Si can be effectively prevented on the contact interfacial surface. Since the B exerts an influence on heat resistance similar to the Ni, when the compound containing B is subject to heat treatment, smaller inter-metallic compounds are educted. In one exemplary embodiment, B content is in the range of about 0.01 at % to about 1.0 at %. When the B content exceeds about 1.0 at % it increases the resistivity of the Al—Ni alloy wiring material and the contact resistance value when the wiring material is in direct contact with the transparent electrode layer. In addition, when B is at such a level, CeB₆ or AlB₂ is educted from the sputtering target to form a layer, and splashing may occur, so that the layer undesirably cannot be normally formed. In contrast, when the B content is less than about 0.01 at % it reduces an ability to preventing the mutual diffusion between Al and Si so that the direct contact with the semiconductor layer cannot be achieved. In detail, when the semiconductor layer directly makes contact with an Al—Ni—Ce—B alloy wiring material having less than about 0.01 at % B and then is subject to heat treatment, the mutual diffusion between the Al and the Si can be achieved in the contact part. In such a situation, the dimple phenomenon may occur as described above. In addition, the B content less than about 0.01 at % causes damage at the contact part making direct contact with the ITO over an extended period of time.

For the above reasons, the exemplary embodiment of an Al—Ni alloy wiring material according to the present invention includes Ni, Ce and B satisfying the inequalities 0.5≦X≦5.0, 0.01≦Y≦1.0, and 0.01≦Z≦1.0, wherein X represents an atomic percentage of Ni content, Y represents an atomic percentage of Ce content, and Z represents an atomic percentage of B content. In another exemplary embodiment, the Al—Ni alloy wiring material includes Ni, Ce and B satisfying the inequalities: 0.5≦X≦2.5, 0.01≦Y≦0.5, and 0.01≦Z≦0.5 wherein X represents an atomic percentage of Ni content, Y represents an atomic percentage of Ce content, and Z represents an atomic percentage of B content. In the above described ranges, the resistivity of a wiring material subject to heat treatment at a temperature of 320° C. becomes about 4.5 μΩ/cm or less, black spot corrosion is decreased when forming the contact hole CH, and the contact resistance value when the wiring material is in direct contact with the transparent electrode layer becomes 100Ω/□10 μm or less. In addition, corrosion resistance against the developer agent used to form the contact hole is ensured. In detail, in one embodiment the etch rate is 24Å/second or less due to the developer.

When an exemplary embodiment of a display apparatus is manufactured using the Al—Ni alloy wiring material according to the present invention a sputtering target in a range satisfying the inequalities 0.5≦X≦5.0, 0.01≦Y≦1.0, and 0.01≦Z≦1.0 is used wherein X represents an atomic percentage of Nickel content, Y represents an atomic percentage of Cerium content, and Z represents an atomic percentage of Boron content. When the sputtering target having the above composition is used, the sputtering target is affected by conditions of the sputtering process. However, an Al—Ni—Ce—B alloy thin film having compositions substantially identical to those of the sputtering target are easily formed.

Although the exemplary embodiment of an Al—Ni alloy wiring material according to the present invention may be used to form a layer through a sputtering method, various alternative methods may be employed. For example, a dry method such as a deposition method or a spray forming method may be employed. Particles including the exemplary embodiment of an Al—Ni alloy composition according to the present invention may be used as a wiring material, and a wiring circuit may be formed through an aerosol deposition method or an ink-jet method.

In order to form an exemplary embodiment of a TFT structure using the exemplary embodiment of an Al—Ni wire, the substrate 1 is provided with the wiring circuit layer 2 disposed thereon, which includes the exemplary embodiment of an Al—Ni alloy wiring material constituting the gate electrode G. The gate electrode G is formed with the gate insulating layer 4 including SiNx formed thereon to protect the gate electrode G.

The a-Si semiconductor layer 5, the channel protective layer 6, the n+-Si semiconductor layer 7 and the wiring layer 2 are sequentially deposited on the gate insulating layer 4. Then, the stacked structure is patterned, thereby forming the drain electrode D and the source electrode S.

The insulating layer 4′ is formed on the drain electrode D and the source electrode S, in which the insulating layer 4′ includes SiNx or resin for planarization of a device surface. In addition, the contact hole CH is formed in the insulating layer 4′ corresponding to a portion of the source electrode S.

In the present exemplary embodiment, the contact hole CH is formed through a photolithography process. The photolithography process will be described below. After coating a photoresist on the substrate 1 on which the drain electrode D, the source electrode S and the insulating layer 4′ of the device are sequentially formed, the photoresist is exposed and developed such that the photoresist corresponding to the contact hole CH is removed. Next, the insulating layer 4′ is etched using the photoresist as a mask to form the contact hole CH so that an upper portion of the source electrode S is exposed. Thereafter, a plasma ashing process is performed with respect to the substrate 1 including the upper portion of the source electrode S. The ashing process removes an organic material residue on the surface of the substrate 1 after the etch process has been performed. The organic material may be a organic material such as photoresist residue on the interfacial surface left during the manufacturing process. Since the organic material is removed through the ashing process, the contact resistance value between the transparent electrode including ITO and the source electrode S is reduced thereafter.

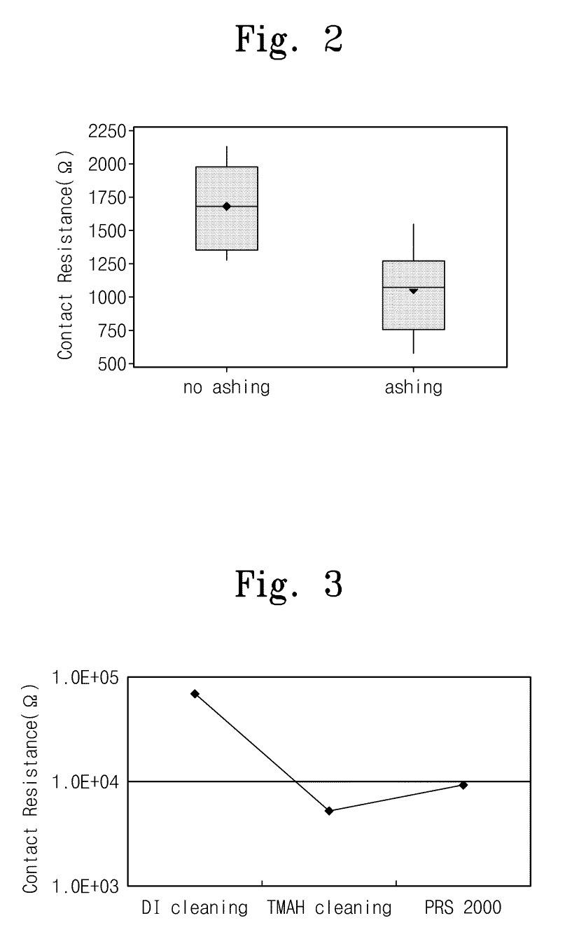

FIG. 2 is a graph showing measured contact resistance values when the ashing process is performed or not. More particularly, FIG. 2 shows the measured contact resistance values when a plasma ashing process is performed by applying oxygen gas at a flow rate of about 400 sccm for about 60 seconds under a power rating of about 150W and when the plasma ashing process is not performed. As shown in FIG. 2, the contact resistance value is significantly reduced after the plasma ashing process has been performed.

The photoresist residue after the ashing process has been performed is stripped by a striper, exemplary embodiments of which include tetramethylammonium hydroxide (“TMAH”) and other materials with similar characteristics. In one exemplary embodiment, the organic material residue on the source electrode S after the ashing process is additionally cleaned using an organic cleaning solution. The additional organic cleaning solution may include an organic solvent, exemplary embodiments of which include TMAH or PRS2000 (manufactured by Dongwoo Fine-Chem Co., Ltd.). The cleaning process based on the organic solvent including TMAH or PRS2000 etches a portion of the surface using the weakness of the Al—Ni alloy for the TMAH, thereby removing an impurity layer from the surface, so that contact resistance is reduced.

FIG. 3 is a graph showing contact resistance between the source electrode S and the ITO layer when the additional cleaning process has been performed using the organic solvent including TMAH or the PR2000 before an ITO electrode is formed. More particularly, FIG. 3 shows the measured contact resistance values when a conventional cleaning process has been performed using deionized water (“DI”) and when the additional cleaning process has been performed using an organic solvent including TMAH diluted to a concentration of about 0.4% with DI, or the PRS2000. As shown in FIG. 3, the additional cleaning process using the organic solvent including TMAH or the PRS2000 significantly reduces the contact resistance as compared with the conventional cleaning process using the DI.

Thereafter, the transparent electrode layer 7′ including ITO or IZO is formed in the contact hole CH.

When the Al—Ni alloy wiring material is used for the wiring circuit layer 2, a cap layer is not interposed between the n+-Si semiconductor layer 7 and the wiring circuit layer 2 or between the transparent electrode layer 7′ and the wiring circuit layer 2 in the contact hole CH, thus reducing manufacturing steps and associated manufacturing costs.

### Embodiment of the Al—Ni Alloy Wiring Material

Hereinafter, the exemplary embodiment of an Al—Ni alloy wiring material according to the present invention will be described in detail.

According to the present exemplary embodiment, the material characteristics of an Al—Ni—Ce—Be alloy were evaluated. A sputtering target was formed by changing Ni, Ce, and B contents according to test sample numbers (No) shown in tables 1 to 7. The sputtering target was formed by mixing metals at a corresponding composition ratio. Next, the metals were melted and stirred under a vacuum state, and cast under an inert gas atmosphere. Then, after rolling and molding an ingot obtained from the metals, the surface of the resultant structure was planarized and provided in a sputter.

Then, after forming a layer using the sputtering target having a composition corresponding to each test sample No., layer and device characteristics were evaluated. The evaluation was performed in terms of resistivity of the layer, corrosion resistance against a developer, a measure of the degree of black spot formation in the contact hole, ITO contact resistance, durability against continuous electrical conduction, i.e., operation lifetime, and irregularity of a contact resistance surface. Hereinafter, the condition of each characteristic evaluation will be described.

<Resistivity of Layer>

The resistivity of the layer was evaluated by forming a single layer having a thickness of 2800 Å on the substrate 1 through sputtering. The resistivity of the single layer was measured by a four-terminal resistance measuring device after the single layer was subject to heat treatment at a temperature of 320° C. for 30 minutes under atmospheric pressure. In order to perform the sputtering, magnetron-sputtering equipment was used where an Argon (Ar) gas was applied at a flow rate of 100 sccm and a pressure of 0.5 Pa under a power of 3.0 Watt/cm².

<Corrosion Resistance against Developer>

The corrosion resistance against developer was evaluated by forming a single layer having a thickness of 2800 Å similarly to the evaluation condition of the above resistivity of layer, using an alkali developer including TMAH developer, and measuring the etch rate of the single layer. The etch rate was calculated by measuring an etched thickness of the single layer after the single layer had been etched for 60 seconds using the TMAH developer having a concentration of 2.38% and a liquid temperature of 23° C.

<Black Spot Created in Contact Hole>

The measure of the degree of black spot formation in the contact hole was evaluated by forming a contact hole in the following sequence and observing the surface of the Al—Ni alloy wiring material exposed through the contact hole.

Regarding the formation of the contact hole, an aluminum alloy layer having a thickness of 2800Å was formed on the substrate 1 using an Al—Ni alloy target having a predetermined composition by the magnetron sputtering equipment wherein Ar gas was introduced at a flow rate of 100 sccm and a pressure of 0.5 Pa under a power of 3.0 Watt/cm². After coating a photoresist (TFR-970 provided by Tokyo Ohka Kogyo Co., Ltd.) on the surface of the Al alloy layer, a 20 μm pattern film used to form a circuit was disposed and then the resultant structure was subject to an exposure process. Thereafter, the photoresist was developed using the TMAH developer having the concentration of 2.38% and a liquid temperature of 23° C. After the development process had been performed, the circuit was formed using an phosphoric acid based mixed acid etchant (made by Kanto Chemical Co., INC.), and the photoresist was removed using the amine aqueous stripping solution (40° C.; TST-AQ8; Tokyo Ohka Kogyo Co., Ltd.). As a result, a circuit including a 50 μm-width Al alloy layer was formed.

The substrate formed with the circuit including the 50 μm-width Al alloy layer was cleaned using the DI and dried. Thereafter, an insulating layer (having a thickness of 4200 Å) including SiNₓ was formed on the substrate. The insulating layer was formed by CVD equipment (PD-2202L made by SAMCO, INC.) under a CVD condition in which ammonia gas, SiH₄ gas, and N₂ gas were applied at flow rates of 10 ccm, 100 ccm, and 200 ccm, respectively, at a pressure of 80 Pa and a substrate temperature of 350° C.

Subsequently, after coating positive photoresist (TFR-970 made by Tokyo Ohka Kogyo Co., Ltd.) on the surface of the insulating layer, a 10 μm×10 μm pattern film for the opening of a contact hole was disposed on the insulating layer and then an exposure process was performed. Thereafter, the development process was performed with respect to the resultant structure using the TMAH developer. Then, a contact hole was formed using a dry etch gas mixture of SF₆ and O₂. In order to form the contact hole, SF₆ and O₂ were applied at flow rates of 60 ccm and 5 ccm at a pressure of 4.0 Pa under power of 100 W.

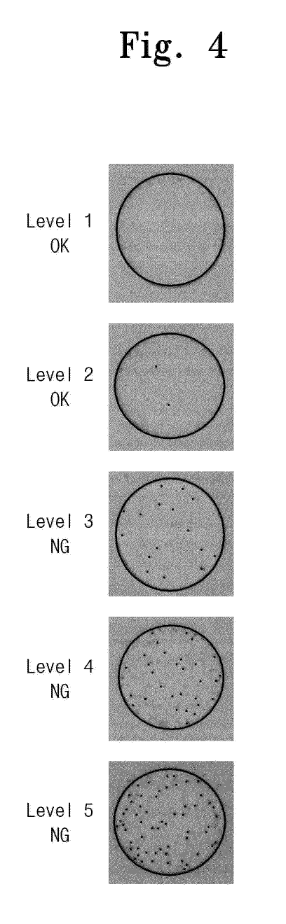

The substrate having the contact hole was evaluated by observing black spots on the Al alloy layer surface exposed in the contact hole by a metallic microscope at 7000 magnifications. The evaluation related to the black spots was performed such that the results were grouped in five levels as shown in FIG. 4. If the substrate corresponds to a first level the number of the black spots is 0, if the substrate is in a second level the number of the black spots is less than 10, but greater than 0. If the substrate falls into the first or second levels, the substrate passes the evaluation. If the substrate corresponds to a third level wherein the number of the black spots is less than 20, but greater than 10, a fourth level wherein the number of the black spots is less than 50, but greater than 20, or a fifth level wherein the number of the black spots is 50 or more, the substrate may not pass the evaluation. Under examination by a scanning electron microscope, the black spots were inspected and determined to be corrosion around an inter-metallic compound.

<ITO Contact Resistance>

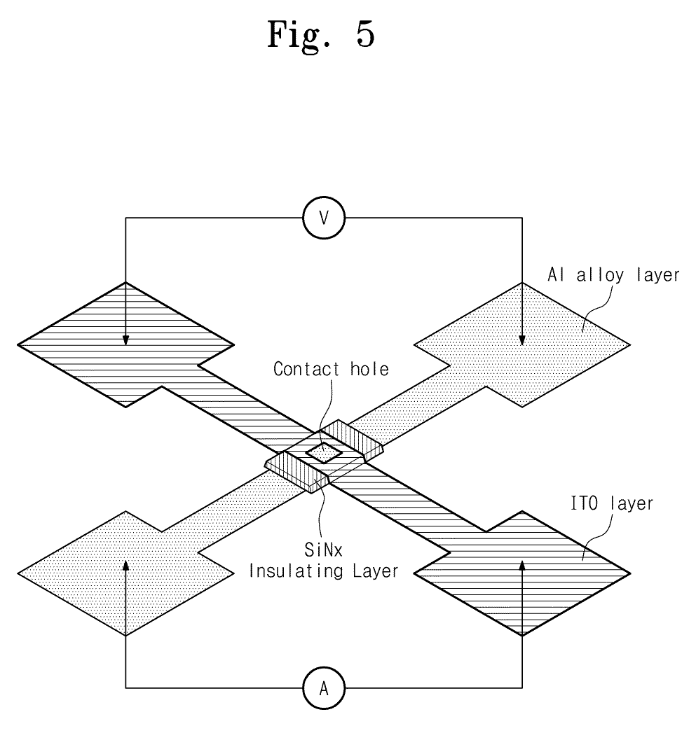

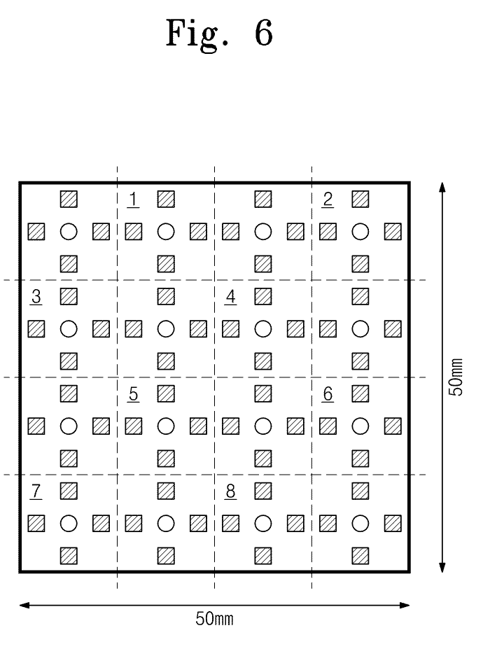

The contact resistance value in the case of the direct contact with an ITO layer was measured using a test sample (Kelvin device) in which an ITO (In₂O₃-10 wt % SnO₂) electrode layer having a thickness of 500 Å and a circuit width of 50 μm was formed on a substrate, and an exemplary embodiment of an Al—Ni alloy layer having a thickness of 2000 Å and a circuit width of 50 μm including the compositions described above crosses the ITO electrode layer as shown in FIG. 5.

The test sample was manufactured by forming an Al alloy layer having a thickness of 2800 Å on a substrate using the Al—Ni alloy target including the compositions under a sputtering condition in which magnetron sputtering equipment was used and Ar gas was applied at a flow rate of 100 ccm and a pressure of 0.5 Pa under power of 1.8 Watt/cm². In the sputtering process, the temperature of the substrate was measured in degrees Celsius (t). After coating a resist (TFR-970 having viscosity of 15 cp and provided by Tokyo Ohka Kogyo Co., Ltd.) on the surface of the Al alloy layer, a 50 μm-width pattern film used to form a circuit was disposed and then the resultant structure was subject to an exposure process. Thereafter, a development process was performed using the TMAH developer having the concentration of 2.38% and a liquid temperature of 23° C. After the development process had been performed, the circuit was formed using phosphoric acid based mixed acid etchant (made by Kanto Chemical Co., INC.), and the resist was removed using the amine aqueous stripping solution (40° C.; TST-AQ8; made by Tokyo Ohka Kogyo Co., Ltd.). As a result, a circuit including an 50 μm-width Al alloy layer was formed.

The substrate formed with the circuit including the 10 μm-width Al alloy layer was cleaned using the DI and dried. Thereafter, the insulating layer having a thickness of 4200 Å including SiNx was formed on the substrate. The insulating layer was formed using CVD equipment (PD-2202L made by SAMCO, INC.) under a CVD condition wherein ammonia gas, SiH₄ gas, and N₂ gas were applied at flow rates of 10 ccm, 100 ccm, and 200 ccm, respectively, at a pressure of 80 Pa and a substrate temperature of 350° C. under power of RF250W.

Subsequently, after coating a positive resist (TFR-970 made by Tokyo Ohka Kogyo Co., Ltd.) on the surface of the insulating layer, a 10 μm×10 μm pattern film for the opening of a contact hole was disposed and then an exposure process was performed. Thereafter, the development process was performed with respect to the resultant structure using the TMAH developer. Then, the contact hole was formed using dry etch gas including SF₆. In order to form the contact hole, SF₆ gas and O₂ gas were applied at flow rates of 50 sccm and 5 sccm at a pressure of 4.0 Pa under a power of 100 W.

The photoresist was stripped by an amine aqueous stripping solution at 40° C. (TST-AQ8 made by Tokyo Ohka Kogyo Co., Ltd.). After removing a remaining stripping solution using isopropyl alcohol, a cleaning process and a drying process were performed. An ITO transparent electrode layer was formed in the contact hole of each sample, the resist of which had been stripped, and around the contact hole using an ITO target (having composition of In₂O₃-10 wt % SnO₂). In order to form the transparent electrode layer, sputtering had been performed at a substrate temperature of 70° C., a power of 1.8 Watt/cm², 80 sccm of a flow rate for argon gas, a flow rate of 0.7 sccm for oxygen gas and a pressure of 0.37 Pa, and an ITO layer had been formed with a thickness of 1000 Å.

After coating a resist (TFR-970 made by Tokyo Ohka Kogyo Co., Ltd.) on the surface of the ITO layer, a pattern film was disposed to perform an exposure process. Then, a development process was performed using a TMAH developer, thereby forming a 50 μm-width circuit using an oxalic acid mixed acid etchant (ITO05N: made by Kanto Chemical Co., Inc.). After the ITO layer circuit had been formed, the resist was removed by the amine aqueous stripping solution at 40° C. (TST-AQ8; Tokyo Ohka Kogyo Co., Ltd.).

Afterwards, each test sample obtained through the manufacturing method was subjected to heat treatment at a temperature of 250° C. under an atmosphere for 30 minutes. Then, continuous electrical conduction (3 mA) was performed at a terminal of the test sample shown in FIG. 5 marked by an arrow to measure resistance.

<Durability for Continuous Electrical Conduction>

The durability for continuous electrical conduction was evaluated by checking whether or not a device was damaged to the point where electrical conduction was impossible after continuous electrical conduction had been performed for 1000 hours with respect to the test sample used in the evaluation of the item “ITO Contact Resistance”. The evaluation was performed by determining the number of test samples that could not electrically conduct after the electrical conduction had continuously been applied with respect to 8 test samples having the same compositions.

<Irregularity of Contact Resistance Surface>

Sixteen devices of FIG. 3 described related to the IPO contact resistance were formed on a 50 mm×50 mm substrate as samples for the evaluation of the irregularity of contact resistance surface as shown in FIG. 6. Then, 8 devices, reference numerals 1 to 3 of FIG. 4, were selected from among the 16 devices, and contact resistance values of the 8 devices were measured. The formation of the devices and the measurement of the contact resistance values were performed similarly to the method described in relation to the ITO contact resistance. In this evaluation, after two sheets of substrates were prepared with respect to each of the compositions of Al-2.0 at % Ni-0.3 at % Ce-0.2 at % B and Al-1.5 at % Ni-0.005 at % Ce-0.005 at % B, the contact resistance values were measured. The results are shown in table 8.

The results obtained through the evaluation are shown tables 1 to 8. to the units of each test sample No. shown in tables 1 to 7 is in atomic percentage (“at %”). In addition, the units of resistivity, corrosion resistance (to developer), a contact resistance value and electrical conduction resistance correspond to μΩcm, Å/S, Ω/□10 μm and a number, respectively In addition, level values of FIG. 4 are inserted into blanks of tables 1 to 7 for black spots generated when the contact hole is formed. In addition, the unit of the irregularity of the contact resistance is Ω/□10 μm.

TABLE 1

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 1-6-1 | 0.4 | 1 | 0 | 3.5 | 6.9 | 1 | 184.4 | 8 |
| 1-7-4 | 0.4 | 1.5 | 0.5 | 4.8 | 7.5 | 1 | 223.5 | 8 |
| 1-1-5 | 0.4 | 0 | 1 | 3.9 | 9.6 | 3 | 29.3 | 3 |

TABLE 2

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 2-4-1 | 0.5 | 0.5 | 0 | 3.4 | 8.0 | 2 | 106.7 | 0 |
| 2-3-2 | 0.5 | 0.01 | 0.01 | 3.1 | 9.7 | 2 | 39.4 | 0 |
| 2-4-2 | 0.5 | 0.5 | 0.01 | 3.5 | 8.1 | 2 | 99.8 | 0 |
| 2-4-4 | 0.5 | 0.5 | 0.5 | 4.1 | 9.3 | 1 | 95.6 | 0 |
| 2-6-4 | 0.5 | 1 | 0.5 | 4.6 | 8.8 | 1 | 143.7 | 0 |
| 2-6-5 | 0.5 | 1 | 1 | 5.1 | 9.3 | 1 | 137.4 | 0 |

TABLE 3

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 3-3-2 | 0.8 | 0.01 | 0.01 | 3.2 | 13.5 | 2 | 33.1 | 0 |
| 3-4-4 | 0.8 | 0.5 | 0.5 | 4.2 | 12.5 | 2 | 80.2 | 0 |
| 3-6-5 | 0.8 | 1 | 1 | 5.2 | 11.8 | 1 | 115.2 | 0 |

TABLE 4

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 4-3-2 | 1.0 | 0.01 | 0.01 | 3.2 | 15.8 | 2 | 29.4 | 0 |
| 4-4-4 | 1.0 | 0.5 | 0.5 | 4.3 | 15.1 | 2 | 71.3 | 0 |
| 4-6-5 | 1.0 | 1 | 1 | 5.3 | 15.1 | 1 | 102.4 | 0 |

TABLE 5

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 5-3-2 | 2.5 | 0.01 | 0.01 | 3.4 | 22.6 | 2 | 16.7 | 0 |
| 5-4-4 | 2.5 | 0.5 | 0.5 | 4.5 | 21.6 | 2 | 40.5 | 0 |
| 5-6-5 | 2.5 | 1 | 1 | 5.4 | 21.6 | 1 | 58.2 | 0 |

TABLE 6

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 6-3-2 | 5.0 | 0.01 | 0.01 | 4 | 25.5 | 4 | 13.0 | 0 |
| 6-4-3 | 5.0 | 0.5 | 0.1 | 4.7 | 21.5 | 2 | 32.8 | 0 |
| 6-4-4 | 5.0 | 0.5 | 0.5 | 5.1 | 24.4 | 2 | 31.6 | 0 |
| 6-6-5 | 5.0 | 1 | 1 | 6 | 24.4 | 2 | 45.4 | 0 |

TABLE 7

| | | | | | | | Contact | Electrical |
|---|---|---|---|---|---|---|---|---|
| Test sample | | | | | Corrosion | Black | resistance | conduction |
| No. | Ni | Ce | B | resistivity | resistance | spots | value | resistance |
| 7-1-4 | 6.0 | 0 | 0.5 | 4.7 | 28.3 | 5 | 8.6 | 0 |
| 7-7-4 | 6.0 | 1.5 | 1 | 6.3 | 23.2 | 2 | 54.7 | 0 |

TABLE 8

| | Al—2.0Ni—0.3Ce—0.2B | | Al—1.5Ni—0.005Ce—0.005B | |
|---|---|---|---|---|
| 1 | 23.2 | 22.5 | 38.5 | 55.3 |
| 2 | 20.3 | 17.5 | 32.2 | 19.8 |
| 3 | 13.0 | 19.6 | 17.8 | 50.4 |
| 4 | 9.1 | 16.7 | 13.4 | 16.6 |
| 5 | 14.9 | 22.2 | 14.9 | 27.9 |
| 6 | 21.6 | 30.6 | 25.0 | 28.3 |
| 7 | 16.9 | 24.4 | 79.6 | 71.9 |
| 8 | 21.7 | 32.0 | 137.9 | 52.0 |
| average | 17.6 | 23.2 | 31.6 | 40.2 |
| Σ | 5.0 | 5.6 | 23.1 | 19.8 |

According to the results shown in tables 1 to 7, if Ce content is 0.01 at % or less, black point corrosion occurs when the contact hole is formed. Meanwhile, although not shown, if Ce content exceeds 1 at %, a crystalline structure of Al₁₁Ce₃ of a sputtering target is expanded, and the segregation of the Ce is created so that the sputtering process may undesirably not be uniformly formed as discussed above.

According to the evaluation result for electrical conduction, if a small amount of the Ni and Ce contents are used, and the B content is 0.01 at % or less, and if a device is continuously conducted, a contact part which makes direct contact with the ITO is damaged according to the passage of time (as shown in most test samples of table 1 and test sample numbers 2-1 and 2-2 of table 2). Although not shown, if the B content exceeds 1.0 at %, CeB₆ or AlB₂ is educted from the sputtering target, splashing may easily occur, and forming a layer is difficult.

In addition, as shown in tables 1 to 7, if the Ni content is 0.5 at % or less, and if a device is continuously conducted, the contact part making direct contact with the ITO is damaged according to the passage of time. If the Ni content exceeds 5.0 at %, black spot corrosion occurs when the contact hole is formed.

Further, if the Ni content is in the range of 0.5 at % to 2.5 at %, the Ce content is in the range of 0.01 at % to 0.5 at %, and the B content is in the range of 0.01 at % to 0.5 at %, the resistivity of a wiring material becomes about 4.5 μΩcm or less after heat treatment has been performed at a temperature of 320° C. Black spot corrosion is also decreased when the contact hole is formed. In addition, a contact resistance value becomes 100 Ω/□10 μm or less when direct contact is made with a transparent electrode layer. In addition, corrosion resistance against the developer can be ensured. In detail, the etch rate becomes 24 Å/S or less by the developer.

Regarding the irregularity of the contact resistance surface, as shown in table 8, in the case of Al-2.0 at % Ni-0.3 at % Ce-0.2 at % B belonging to the composition range of the present invention, the irregularity of the contact resistance value is small regardless of the device position of the substrate, and a representing the irregularity of the contact resistance value is in the range of about 5.0 to about 6.0. In the case of Al-1.5 at % Ni-0.005 at % Ce-0.005 at % B beyond the composition range of the present invention, the contact resistance value is significantly irregular according to the device positions in the substrate. Accordingly, σ is in the range of about 19 to about 24.

Even if a contact resistance value is slightly irregular across one sheet of a substrate (panel) constituting a display apparatus, if a driving frequency is 60 Hz, serious problems are not caused in the display apparatus. If the driving frequency is doubled, i.e., to 120 Hz, a normal display operation may not be performed due to an operating failure due to the contact resistance irregularity. Accordingly, if Al—Ni—Ce—B alloy wiring material in the composition range according to the present invention is employed, a display apparatus capable of realizing a superior contact state with the ITO layer and performing a normal display operation even in a doubled driving frequency can be manufactured.

As described above, the embodiments of an Al—Ni alloy wiring material according to the present invention provide superior corrosion resistance against a developer and superior corrosion resistance when a contact hole is formed. Accordingly, a device wherein the wiring material contacts a transparent electrode including ITO can be stably manufactured. Accordingly, even a device formed in an opposing substrate, e.g., a common electrode substrate, can have a constant contact resistance value.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An aluminum-nickel alloy wiring material, the material comprising:
Aluminum, Nickel, Cerium, and Boron.

2. The aluminum-nickel alloy wiring material of claim 1, wherein the Nickel, Cerium, and Boron satisfy following inequalities:
0.5≦X≦5.0;
0.01≦Y≦1.0; and
0.01≦Z≦1.0, respectively,
wherein X represents an atomic percentage of Nickel content, Y represents an atomic percentage of Cerium content, and Z represents an atomic percentage of Boron content.

3. The aluminum-nickel alloy wiring material of claim 1, wherein the Nickel, Cerium, and Boron satisfy following inequalities:
0.5≦X≦2.5;
0.01≦Y≦0.5; and
0.01≦Z≦0.5, respectively,
wherein X represents an atomic percentage of Nickel content, Y represents an atomic percentage of Cerium content, and Z represents an atomic percentage of Boron content.

4. The aluminum-nickel alloy wiring material of claim 1, wherein the Nickel and Cerium satisfy following inequalities:
0.5≦X≦5.0;
0.01≦Y≦1.0, respectively,
wherein X represents an atomic percentage of Nickel content, and Y represents an atomic percentage of Cerium content.

5. The aluminum-nickel alloy wiring material of claim 4, wherein the Boron and Cerium satisfies following inequality:
0.01≦Z≦1.0,
wherein Z represents an atomic percentage of Boron content.

6. A thin film transistor comprising:
a first wiring circuit layer;
a semiconductor layer disposed on the first wiring circuit layer;
a second wiring circuit layer disposed on the semiconductor layer; and
a transparent electrode layer disposed on the semiconductor layer,
wherein at least one of said first and second wiring circuit layers comprises Aluminum, Nickel, Cerium, and Boron and wherein at least a portion of the second wiring circuit layer contacts the transparent electrode layer.

7. The thin film transistor of claim 6, wherein the Nickel, Cerium, and Boron satisfy following inequalities:
0.5≦X≦5.0;
0.01≦Y≦1.0; and
0.01≦Z≦1.0, respectively,
wherein X represents an atomic percentage of Nickel content, Y represents an atomic percentage of Cerium content, and Z represents an atomic percentage of Boron content.

8. The device of claim 7, wherein a portion of the second wiring circuit layer directly contacts the semiconductor layer.

9. The thin film transistor of claim 6, wherein the Nickel, and Cerium satisfy following inequalities:
0.5≦X≦2.5;
0.01≦Y≦0.5, respectively,
wherein X represents an atomic percentage of Nickel content, and Y represents an atomic percentage of Cerium content.

10. The thin film transistor of claim 6, wherein the Boron satisfies following inequality:
0.01≦Z≦0.5,
wherein Z represents an atomic percentage of Boron content.

11. A thin film transistor substrate comprising:
a substrate;
a third wiring circuit layer disposed on the substrate and comprising a gate electrode;
a gate insulating layer disposed on the substrate;
a semiconductor layer disposed on the gate insulating layer;
a fourth wiring circuit layer disposed on the semiconductor layer and comprising a source electrode and a drain electrode;
an insulating layer disposed on the source electrode and the drain electrode and comprising a contact hole corresponding to a portion of the source electrode; and
a transparent electrode disposed on the insulating layer and electrically connected with the source electrode through the contact hole,
wherein at least one of said third and fourth wiring circuit layers comprise Aluminum, Nickel, Cerium and Boron.

12. The thin film transistor substrate of claim 11, wherein at least said portion of the second wiring circuit layer directly contacts the transparent electrode.

13. The thin film transistor substrate of claim 12, wherein the Nickel and Boron satisfy following inequalities:
0.5≦X≦5.0;
0.01≦Y≦1.0; respectively,
wherein X represents an atomic percentage of Nickel content and Y represents an atomic percentage of Boron content.

14. The thin film transistor substrate of claim 13, wherein the Cerium satisfies following inequality:
0.01≦Z≦1.0,
wherein Z represents an atomic percentage of Cerium content.

15. The thin film transistor substrate of claim 12, wherein the Nickel and Boron satisfy following inequalities:
0.5≦X≦2.5;
0.01≦Y≦0.5; respectively,
wherein X represents an atomic percentage of Nickel content and Y represents an atomic percentage of Boron content.

16. The thin film transistor substrate of claim 15, wherein the Cerium satisfies following inequality:
0.01≦Z≦0.5,
wherein Z represents an atomic percentage of Cerium content.

17. The thin film transistor substrate of claim 11, further comprising a contact barrier layer disposed on said at least one of the third and fourth wiring circuit layers.

18. A sputtering target comprising:
Aluminum, Nickel, Cerium and Boron,
wherein the Nickel, Cerium and Boron satisfy following inequalities:
0.5≦X≦5.0;
0.01≦Y≦1.0; and
0.01≦Z≦1.0, respectively,
wherein X represents an atomic percentage of Nickel content, Y represents an atomic percentage of Cerium content, and Z represents an atomic percentage of Boron content.

19. A method of manufacturing a thin film transistor substrate, the method comprising:
disposing a thin film transistor on a substrate, the thin film transistor comprising:
a fifth wiring circuit layer disposed on the substrate;
a semiconductor layer disposed on the wiring circuit layer; and
a sixth wiring circuit layer disposed on the semiconductor layer;
coating a photoresist on the substrate;
removing a portion of the photoresist;
etching an insulating layer using the photoresist as a mask to expose a portion of the sixth wiring circuit layer through a contact hole;
ashing the substrate;
stripping the photoresist;
cleaning the substrate with an cleaning solution; and
disposing a transparent electrode on the insulating layer such that the transparent electrode is connected to the sixth wiring circuit layer through the contact hole,
wherein at least one of said fifth and sixth wiring circuit layers comprises Aluminum, Nickel, Cerium, and Boron, and
wherein the Nickel, Cerium and Boron satisfy the following inequalities:
0.5≦X≦5.0;
0.01≦Y≦1.0; and
0.01≦Z≦1.0, respectively,
wherein X represents an atomic percentage of Nickel content, Y represents an atomic percentage of Cerium content and Z represents an atomic percentage of Boron content.

20. The method of claim 19, wherein the cleaning solution comprises tetramethylammonium hydroxide.
